(19) United States
(12) Patent Application Publication
(10) Pub. No.: US 2024/0362114 A1
(43) Pub. Date: Oct. 31, 2024

(54) MEMORY MANAGEMENT HOLDING LATCH PLACEMENT AND CONTROL SIGNAL GENERATION

(71) Applicant: Micron Technology, Inc., Boise, ID (US)

(72) Inventors: Jaeil Kim, Boise, ID (US); Donald M. Morgan, Meridian, ID (US); Alan J. Wilson, Boise, ID (US)

(21) Appl. No.: 18/607,152

(22) Filed: Mar. 15, 2024

Related U.S. Application Data
(60) Provisional application No. 63/499,134, filed on Apr. 28, 2023.

(51) Int. Cl. G06F 11/10

(52) U.S. Cl. CPC G06F 11/1068; G06F 11/1016

(57) ABSTRACT

A system for providing memory management holding latch placement and control signal generation is disclosed. The system performs memory management operations on a memory device to reduce memory cell wear and tear and to balance use of the memory cells of the memory device. The system separates memory management read operations from memory management write operations by utilizing a holding register that stores data from a source memory cell prior to transfer to a target memory cell. When a memory management read operation is initiated, data and error correction parity bits from the source memory cell are provided to a circuit including the holding register. The data and parity bits are analyzed for errors and the errors are corrected prior to storing the data and parity bits into the holding register. The data and associated parity bits are then transferred from the holding register to the target memory cell.

### RELATED APPLICATIONS

The present application claims priority to and the benefit of Prov. U.S. Pat. App. Ser. No. 63/499,134, filed on Apr. 28, 2023, which is hereby incorporated by reference in the present disclosure in its entirety.

### FIELD OF THE TECHNOLOGY

At least some embodiments disclosed herein relate to memory devices in general, and more particularly, but not limited to, memory management holding latch placement and control signal generation.

### BACKGROUND

Typically, a computing device or system includes one or more processors and one or more memory devices, such as memory chips or integrated circuits. The memory devices may be utilized to store data that may be accessed, modified, deleted, or replaced. The memory devices may be, for example, non-volatile memory devices that retain data irrespective of whether the memory devices are powered on or off. Such non-volatile memories may include, but are not limited to, read-only memories, solid state drives, and NAND flash memories. Additionally, the memory devices may be volatile memory devices, such as, but not limited to, dynamic or static random-access memories, which retain stored data while powered on, but are susceptible to data loss when powered off. Based on receipt of an input, the one or more processors of the computing device or system may request that a memory device of the computing system retrieve stored data associated with or corresponding to the input. In certain scenarios, the data retrieved from the memory device may include instructions, which may be executed by the one or more processors to perform various operations and may include data that may be utilized as inputs for the various operations. In instances where the one or more processors perform operations based on instructions from the memory device, data resulting from the performance of the operations may be subsequently stored into the memory device for future retrieval.

While current memory technologies provide for various functionality and benefits, situations often arise that may potentially cause degradation to the memory devices, potential data loss, damage to memory cells of the memory devices, among potential harmful effects to the memory devices. For example, certain memory cells of a memory array may be the target of a disproportionate number of read operations, write operations, other operations, or a combination thereof, when compared to other memory cells of the memory array. In such instances, such memory cells may wear out faster than other less-frequently-used memory cells. Various techniques exist for extending the life of memory cells and balancing memory usage in memory devices. For example, wear leveling is a memory management technique that can extend the useful life of the memory cells of a device by effectively spreading memory usage across the various sections of the memory array so that the sections experience comparable memory usage. Wear leveling, for example, may involve transferring data from a source memory row located in a section of a memory array to target rows that may be located in another section of the memory array and then mapping the addresses of the source memory rows to addresses corresponding to the target memory rows. Memory management technologies may be enhanced to reduce the amount of memory resources utilized to conduct memory management, reduce errors in data and error correction bits, and further extend the life of memory.

### BRIEF DESCRIPTION OF THE DRAWINGS

The embodiments are illustrated by way of example and not limitation in the figures of the accompanying drawings in which like references indicate similar elements.

FIG. 1 illustrates a schematic diagram of a system including memory management holding latch placement and control signal generation in accordance with embodiments of the present disclosure.

FIG. 2 illustrates a schematic diagram illustrating holding register traffic in accordance with embodiments of the present disclosure.

FIG. 3 illustrates an exemplary memory management holding register implementation in accordance with embodiments of the present disclosure.

FIG. 4 illustrates an exemplary datapath flow for a memory management read operation for data in accordance with embodiments of the present disclosure.

FIG. 5 illustrates an exemplary datapath flow for a memory management read operation for an error correction parity bit in accordance with embodiments of the present disclosure.

FIG. 6 illustrates an exemplary datapath flow for a memory management write operation in accordance with embodiments of the present disclosure.

FIG. 7 illustrates an exemplary datapath flow for a memory management write operation for an error correction parity bit in accordance with embodiments of the present disclosure.

FIG. 8 illustrates an exemplary datapath flow for a memory management match read operation in accordance with embodiments of the present disclosure.

FIG. 9 illustrates an exemplary datapath flow for a memory management match read operation for an error correction parity bit in accordance with embodiments of the present disclosure.

FIG. 10 illustrates an exemplary datapath flow for a memory management match write operation in accordance with embodiments of the present disclosure.

FIG. 11 illustrates an exemplary datapath flow for a memory management match write for an error correction parity bit in accordance with embodiments of the present disclosure.

FIG. 12 illustrates an exemplary datapath flow for a memory management match mask write operation in accordance with embodiments of the present disclosure.

FIG. 13 illustrates an exemplary datapath flow for a memory management match mask write operation for an error correction parity bit in accordance with embodiments of the present disclosure.

FIG. 14 illustrates a method for providing memory management holding latch placement and control signal generation in accordance with embodiments of the present disclosure.

FIG. 15 illustrates a schematic diagram of a machine in the form of a computer system within which a set of instructions, when executed, may cause the machine to exercise memory management holding latch placement and control signal generation according to embodiments of the present disclosure.

### DETAILED DESCRIPTION

The following disclosure describes various embodiments for systems and methods for providing memory management holding latch placement and control signal generation. At least some embodiments of the present disclosure relate to memory device technologies for mitigating the wear and tear associated with overusing memory cells in a memory device and extending the life of the memory cells. In certain embodiments, the systems and methods may incorporate the use of memory management technologies and techniques, such as, but not limited to, wear leveling (including static, dynamic, and other forms of wear leveling), TRIM, garbage collection, memory balancing, and other memory management technologies and techniques to facilitate balancing of memory usage more evenly among the various memory cells of a memory device. For example, in a traditional wear leveling memory management operation (or function), the various memory management operations associated with the wear leveling operation are conducted one after the other such that the source cell (or row), from which the data is obtained, and target cell (or row), to which the data is ultimately transferred to from the source cell, are unavailable for the duration of the wear leveling process. Such lockup periods (e.g., memory management cycle time) for memory cells (or rows) reduce the availability of the memory cells for access by other devices, such as a host device, and also slow down the processing of requests for data stored in memory cells. To reduce the unavailability of memory cells and to enhance processing of requests by a memory device, the systems and methods may include separating a memory management function or process into a memory management read operation, a memory management write operation, and other memory management operations. The separating of the memory management operations may be utilized to reduce the duration of time that the memory cells undergoing the memory management process are unavailable to host devices that may seek to access or modify the data stored in the memory cells.

For example, the systems and methods may integrate a memory management holding register into the datapath of a circuit of a memory device, while also ensuring access to error correction code (ECC) corrected data. The systems and methods are configured to support a superset of normal datapath and holding register traffic. For example, the superset of normal datapath and holding register traffic supported by the systems and methods may enable the systems and methods to process and handle requests for data stored in the memory cells of the memory arrays of a memory device, but also simultaneously handle requests for data that are stored in the holding registers provided in the present disclosure. Similarly, write operations, erase operations, and other operations may also be conducted with respect to the memory cells of the memory arrays and also to the holding registers. In certain embodiments, the system and methods may also correct and store ECC parity bits in the holding register, along with the data bits from the source memory cell to allow for a target write to a target memory cell without having to generate new parity bits. In certain embodiments, the foregoing components and their associated functionality also allow any accumulated soft errors to be corrected on subsequent memory reads or scrubs. In certain embodiments, the system and methods also enable host devices to request data, modify data, erase data, or otherwise interact with the data sooner than traditional memory management operations. For example, once data is read and received from a source memory cell (or row) and stored in the holding register as the result of a memory management read operation of a memory management function, the data stored in the holding register may be mapped to or associated with a source row address. A host device may request the data and if the address associated with the request matches the source row address, the host device may read, modify, or otherwise interact with the data stored in the holding register-even though the data has not yet been transferred to the target memory cell (or row) from the holding register. By enabling the host device to access the data before the memory management operations (or function) is completed using the features of the present disclosure, a greater number of memory operations may be conducted than when compared to implementations for traditional memory management functions. Eventually, a memory management write operation for the memory management function may be executed so that the data stored in the holding register is transferred to the target memory cell (or row). Once the data is transferred to the target memory cell, the source row address may be mapped to the target memory row and the data may continue to be accessed using the original address going forward. In certain embodiments, the data movement and address remap may be performed by the memory device as part of a wear leveling and/or other memory management operation and/or sequence. In certain embodiments, from the perspective of the host, there appears to be no change occurring as the foregoing operations are conducted.

In certain embodiments, a memory device for providing memory management holding latch placement and control signal generation is provided. In certain embodiments, the memory device may include one or more memory arrays including a plurality of memory cells configured to store data. In certain embodiments, the memory device may also include a circuit configured to perform a variety of operations and functionality. In certain embodiments, the circuit may be configured to receive, for a memory management read operation of a memory management function, data from a source memory cell of the plurality of memory cells and one or more error correction parity bits associated with the data for transfer to a target memory cell of the plurality of memory cells. In certain embodiments, the circuit may be configured to determine whether the data from the source memory cell has a data error. In certain embodiments, the circuit may be configured to determine whether the one or more error correction parity bits associated with the data has a parity bit error. In certain embodiments, the circuit may be configured to perform error correction on the data if the data from the source memory cell is determined to have the data error. In certain embodiments, the circuit may be configured to perform error correction on the one or more error correction parity bits if the one or more error correction parity bits are determined to have the parity bit error. In certain embodiments, the circuit may be configured to store, in a holding register, the data and the one or more error correction parity bits until the data and the one or more error correction parity bits are transferred to the target memory cell.

In certain embodiments, the circuit may be further configured to transfer, such as for a memory management write operation of the memory management function, the data, the one or more error correction parity bits, or a combination thereof, from the holding register to the target memory cell. In certain embodiments, the circuit may be further configured to transfer, for a memory management write operation and from the holding register, the data, the one or more error correction parity bits, or a combination thereof, to a redundant memory cell of the plurality of memory cells. In certain embodiments, the circuit may be further configured to maintain a mapping of address assignments to be updated when the data, the one or more error correction parity bits, or a combination thereof, move from a source memory cell to the holding register. In certain embodiments, the circuit may be further configured to receive, from a controller, a request to read the data. In certain embodiments, the circuit may be further configured to determine whether an address associated with the request to read the data matches with a holding register address mapping for the holding register storing the data. In certain embodiments, the circuit may be further configured to provide, if the address associated with the request matches with the mapped holding register address, the data from the holding register to the controller. In certain embodiments, the circuit may be further configured to perform error correction on the data stored in the holding register prior to providing the data from the holding register to the controller in response to the request to read the data.

In certain embodiments, the circuit may be further configured to receive, from a controller, a request to write new data. In certain embodiments, the circuit may be further configured to determine whether an address associated with the request to write the new data matches with a holding register address mapping for the holding register storing the data. In certain embodiments, the circuit may be further configured to write, if the address associated with the request matches with the mapped holding register address, the new data received from the controller to the holding register. In certain embodiments, the circuit may be further configured to calculate one or more error correction parity bits for the new data. In certain embodiments, the circuit may be further configured to store the at least one error correction parity bit for the new data in the holding register.

In certain embodiments, the circuit may be further configured to receive, from a controller, a request to perform a mask write operation to overwrite a portion of the data with new data. In certain embodiments, the circuit may be further configured to determine whether an address associated with the request to perform the mask write operation matches with a holding register address mapping for the holding register storing the data. In certain embodiments, the circuit may be configured to retrieve, if the address matches with the mapped holding register address, a remaining portion of the data from the holding register. In certain embodiments, the circuit may be configured to combine the new data with the remaining data to create combined data. In certain embodiments, the circuit may be configured to store the combined data into the holding register. In certain embodiments, the circuit may be further configured to calculate one or more error correction parity bits for the combined data. In certain embodiments, the circuit may be further configured to store the one or more error correction parity bits for the combined data in the holding register.

In certain embodiments, the circuit may be further configured to correct soft errors (e.g., accumulated soft errors that do not result from damage to the memory device itself) associated with the data on a subsequent request to read the data from the holding register. In certain scenarios, if new parity bits are generated for data, a soft error that occurs that is supported by the new parity bits may become undetectable in traditional implementations. The functionality provided by the present disclosure avoids such a situation from occurring. In a traditional implementation, if new parity is calculated for data that contains an error, the new parity bit may maintain the error even after an error correction is performed on the data. By utilizing the holding register and circuit containing the bit flip/error correction component, any accumulated soft errors may be corrected on subsequent reads or scrubs conducted using the memory device. Also, since the corrected and stored parity bits are stored in the holding register and may be stored with the data bits that the parity bits are associated with, the systems and methods allow for a target-write without requiring the generation of new parity.

In certain embodiments, a method for providing memory management latch placement and control signal generation is provided. In certain embodiments, the method may include receiving, at a circuit of a memory device and for a memory management read operation associated with a memory management function associated with a command, data from a source memory cell of the memory device and at least one error correction parity bit associated with the data. In certain embodiments, the method may include storing, in a holding register of the circuit, the data and the one or more error correction parity bits, and remapping the holding register to the address of the source memory cell. In certain embodiments, the method may include receiving, from a controller, a request to read the data. In certain embodiments, the method may include determining whether an address associated with the request to read the data matches with a holding register address for the holding register storing the data. In certain embodiments, the method may include providing, if the address associated with the request matches with the holding register address, the data from the holding register to the controller. In certain embodiments, the method may include transferring, from the holding register and for a memory management write operation associated with the memory management function, the data and the at least one error correction parity bit associated with the data to a target memory cell and remapping the target memory cell to the address of the source memory cell.

In certain embodiments, the method may include receiving the command to perform the memory management function on the memory device. In certain embodiments, the method may include performing error correction on the data prior to storing the data in the holding register of the circuit of the memory device if the data is determined to have an error. In certain embodiments, the method may include performing error correction on the one or more error correction parity bits if the one or more error correction parity bits are determined to have a parity bit error. In certain embodiments, the method may include receiving, from the controller, a request to write new data. In certain embodiments, the method may include determining whether an address associated with the request to write the new data matches with the holding register address for the holding register storing the data. In certain embodiments, the method may include writing, if the address associated with the request matches with the holding register address, the new data received from the controller to the holding register. In certain embodiments, the method may include calculating one or more error correction parity bits for the new data. In certain embodiments, the method may include storing the one or more error correction parity bits for the new data in the holding register. In certain embodiments, the method may include transferring the data and the one or more error correction parity bits to a redundant memory cell.

In certain embodiments, the method may include receiving, from the controller, a request to perform a mask write operation to overwrite a portion of the data with new data. In certain embodiments, the method may include retrieving, if an address associated with the request to perform the mask write operation matches with the holding register address, a remaining portion of the data from the holding register. In certain embodiments, the method may include mixing the new data with the remaining data to create mixed data. In certain embodiments, the method may include storing the mixed data into the holding register.

A system for providing memory management latch placement and control signal generation is provided. In certain embodiments, the system may include a host device including a controller and a memory device including a plurality of memory cells and a circuit configured to perform a plurality of operations of the system. In certain embodiments, the circuit may be configured to receive, such as for a memory management read operation associated with a memory management function associated with a command, data from a source memory cell of the memory device and one or more error correction parity bits associated with the data. In certain embodiments, the circuit may be configured to store, in a holding register of the circuit, the data and the one or more error correction parity bits and to remap the holding register to the address of the source memory cell. In certain embodiments, the circuit may be configured to receive, from a controller, a request to write new data. In certain embodiments, the circuit may be configured to determine whether an address associated with the request to write the new data matches with a holding register address for the holding register storing the data. In certain embodiments, the circuit may be configured to write, if the address associated with the request matches with the holding register address, the new data received from the controller to the holding register. In certain embodiments, the circuit may be configured to calculate one or more new error correction parity bits for the new data. In certain embodiments, the circuit may be configured to transfer, from the holding register and for a memory management write operation associated with the memory management function, the new data and the at least one new error correction parity bit for the new data to a target memory cell and to remap the target memory cell to the address of the source memory cell.

In certain embodiments, an additional system is provided. In certain embodiments, the system may include a host device comprising a controller and a memory device. In certain embodiments, the memory device may include at least one input-output pad, a plurality of memory cells of at least one memory array, at least one sense amplifier configured to sense data stored in the plurality of memory cells. In certain embodiments, the memory device may also include a circuit positioned into a datapath of the memory device and having access to the at least one sense amplifier and the at least one input-output pad via the datapath. In certain embodiments, the circuit may include a holding register and may be configured to receive, for a memory management read operation associated with a memory management function associated with a command, data from a source memory cell of the plurality of memory cells and at least one error correction parity bit associated with the data. In certain embodiments, the circuit may be configured to store, in the holding register of the circuit, the data and the at least one error correction parity bit. In certain embodiments, the circuit may be configured to receive, from the controller, a request to write new data, wherein the request is received via the at least one input-output pad and the datapath. In certain embodiments, the circuit may be configured to determine whether an address associated with the request to write the new data matches with a source row address mapped to the holding register storing the data. In certain embodiments, the circuit may be configured to write, if the address associated with the request matches with the source row address mapped to the holding register storing the data, the new data received from the controller to the holding register. As a result, based on the mapping of the source row address to the holding register, the holding register will respond to the address of the source memory cell when a request for data associated with the source address is received and the data is stored in the holding register. In certain embodiments, the circuit may be configured to facilitate calculation of at least one new error correction parity bit for the new data. In certain embodiments, the circuitry may be configured to transfer, from the holding register and for a memory management write operation associated with the memory management function, the new data and the at least one new error correction parity bit for the new data to a target memory cell. In certain embodiments, the target memory cell may be remapped to the address of the source memory cell once the new data and/or the at least one new error correction parity bit are transferred to the target memory cell so that the target memory cell will respond when a request for data associated with the source address is received and the data is stored in the target memory cell.

In certain embodiments, the system may include an error correction component positioned in the datapath of the memory device and having access to the circuit comprising the holding register via the datapath. In certain embodiments, the error correction component may be positioned in the datapath such that the error correction component has access to the at least one sense amplifier. In certain embodiments, the error correction component may be configured to facilitate calculation of the at least one new error correction parity bit for the new data. In certain embodiments, the error correction component may be positioned in the datapath of the memory device and having access to the input-output pads via the datapath.

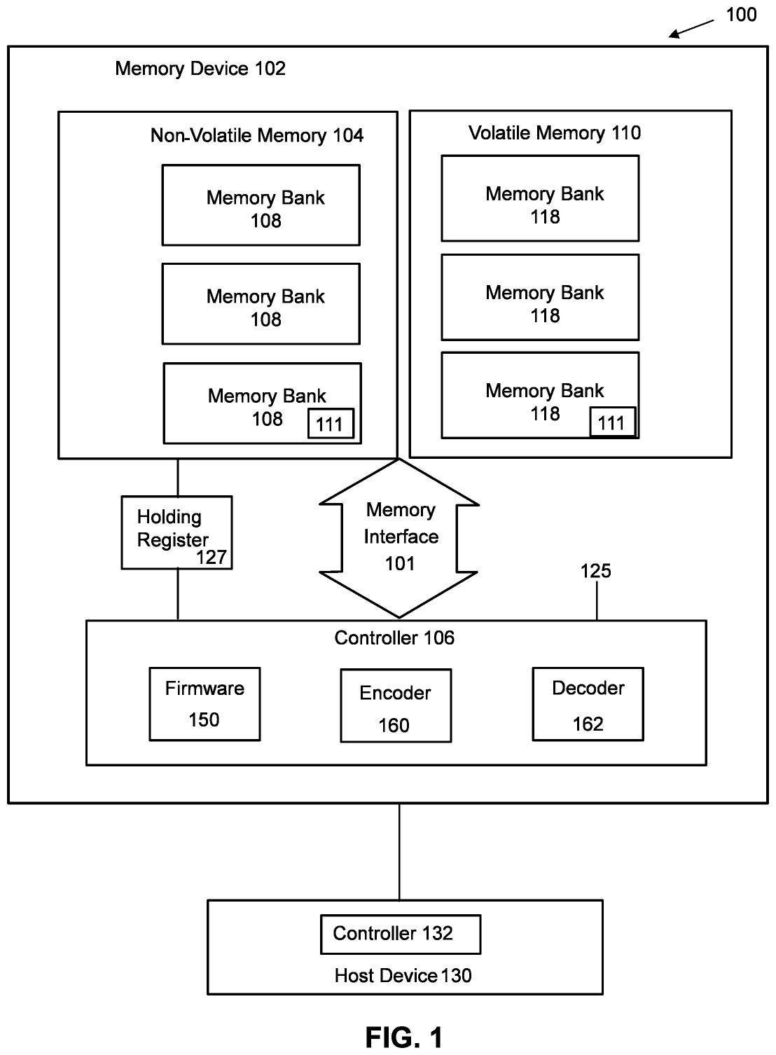

Referring now also to FIG. 1, FIG. 1 illustrates an exemplary architecture for system 100 including a memory device 102 and host device 130 that may be utilized to provide memory management holding latch placement and control signal generation in accordance with embodiments of the present disclosure. In certain embodiments, the memory device 102 and other componentry illustrated in the Figures may belong to a system 100. In certain embodiments, the memory device 102 is, for example, but not limited to, an SSD, eMMC, memory card, or other storage device, or a NAND-based flash memory chip or module that is capable of encoding and decoding stored data, such as by utilizing an encoder 160 and decoder 162 of the memory device 102. In certain embodiments, the memory device 102 may include any amount of componentry to facilitate the operation of the memory device 102. In certain embodiments, for example, the memory device 102 may include, but is not limited to including, a non-volatile memory 104, memory banks 108, a volatile memory 110, sense amplifiers 111, memory banks 118, a memory interface 101, a controller 106 (which, in certain embodiments, may include the encoder 160, a decoder 162, firmware 150, and/or other componentry), a holding register 127, any other componentry, or a combination thereof. In certain embodiments, the memory device 102 may communicatively link with a host device 130, which may be or include a computer, server, processor, autonomous vehicle, any other computing device or system, or a combination thereof. In certain embodiments, the host device 130 may include a controller 132, which may be configured to control the operative functions of the host device 130, issue commands for the memory device 102, receive data from the memory device 102, modify data stored in the memory device 102, write data in the memory device 102, erase data on the memory device 102, perform other actions (e.g., wear leveling actions, other memory management actions, or a combination thereof) with respect to the memory device 102, or a combination thereof.

In certain embodiments, the non-volatile memory 104 may be configured to retain stored data irrespective of whether there is power delivered to the non-volatile memory 104. In certain embodiments, the non-volatile memory 104 may be configured to include any number of memory banks 108 that may be configured to store user data, any other type of data, or a combination thereof. In certain embodiments, the memory banks 108 may be activated and opened, such as upon receipt of an activate command from the host device 130 or other device. In certain embodiments, the memory banks 108 may be closed, such as upon receipt of a precharge command from the host device 130 or other device. In certain embodiments, the memory banks 108 of the non-volatile memory 104 may be configured to include a plurality of physical memory cells configured to store data. Any number of memory cells may be included in the memory banks 108. In certain embodiments, the non-volatile memory 104 may include a physical memory array including an array of bit cells, each of which may be configured to store at least one bit of data (e.g., to allow for single cell NAND implementations and/or multi-level cell NAND implementations). In certain embodiments, each bit cell may be connected to a wordline and bitline. In certain embodiments, the memory cells of the non-volatile memory 104 may be etched onto the silicon wafer forming the base of the non-volatile memory. The memory cells may be etched in an array of columns (e.g., bitlines) and rows (e.g., wordlines). In certain embodiments, the intersection of a particular bitline with a wordline may serve as the address of the memory cell. In certain embodiments, for each combination of address bits, the memory device 102 may be configured to assert a wordline that activates the bit cells in a particular row of a memory bank 108. For example, in certain embodiments, when the wordline is high, the stored bit may be configured to transfer to or from the bitline. On the other hand, in certain embodiments, when the wordline is not high, the bitline may be disconnected from the cell. In certain embodiments, the memory banks 108 may include any number of sense amplifiers 111, which may be configured to sense charges from the memory banks 108 and amplify the voltage to enable the host device 130 to interpret the data stored in a particular memory bank 108. In certain embodiments, each memory bank 108 may be physically and/or communicatively linked with the holding register 127, which may be utilized to store data from the memory banks 108, 118.

In certain embodiments, the volatile memory 110 may also be configured to retain stored data, however, in certain embodiments, may not retain the data after power is no longer provided to the volatile memory 110 or to the memory device 102. In certain embodiments, the volatile memory 110 may include a plurality of memory banks 118, which may be similarly activated and opened, such as upon receipt by the memory device 102 of an activate command, such as from the host device 130 and/or the controller 106. In certain embodiments, the memory banks 118 may include any of the componentry and/or functionality as for the memory banks 108. For example, the volatile memory 110 may include a physical memory array including an array of bit cells configured to store data. Bit cells in a particular row of a memory bank 118 may be activated in response to receipt of an activate command, such as issued by a host device 130. In certain embodiments, the memory banks 118 may include sense amplifiers 111, which may be configured to sense charges from the memory banks 118 and amplify the voltage to enable the host device 130 to interpret the data stored in a particular memory bank 118. In certain embodiments, each memory bank 118 may physically and/or communicatively linked with holding register 127.

In certain embodiments, the controller 106 of the memory device 102 may be configured to control access to the non-volatile memory 104, the volatile memory 110, any other componentry of the memory device 102, or a combination thereof. In certain embodiments, data may be provided by controller 106 to the non-volatile memory 104, the volatile memory 110, or a combination thereof, such as by utilizing memory interface 101. For example, the data may be obtained from the host device 130 to be stored in the non-volatile memory 104, such as in a memory bank 108. In certain embodiments, the controller 106 may include an encoder 160 for generating ECC data (e.g., such as when writing data to the non-volatile memory 104), and a decoder 162 for decoding ECC data (e.g., when reading data, such as from the non-volatile memory 104). In certain embodiments, the controller 106 may include firmware 150, which may be configured to control the components of the system 100. In certain embodiments, the firmware 150 may be configured to control access to the non-volatile memory 104, the volatile memory 110, or a combination thereof, by the host device 130 and control the operative functionality of the memory device 102. Additionally details relating to the firmware 150 are discussed below. In certain embodiments, the controller 106 may physically and/or communicatively linked to the holding register 127.

As indicated above, the memory device 102 may be configured to receive data (e.g., user data) to be stored from host device 130 (e.g., over a serial communications interface, or a wireless communications interface). In certain embodiments, the user data may be video data from a device of a user, sensor data from one or more sensors of an autonomous or other vehicle, text data, audio data, virtual reality data, augmented reality data, information, content, any type of data, or a combination thereof. In certain embodiments, memory device 102 may be configured to store the received data in memory cells of non-volatile memory 104, the volatile memory 110, or a combination thereof. In certain embodiments, the memory cells may be provided by one or more non-volatile memory chips, volatile memory chips, or a combination thereof. In certain embodiments, the memory chips may be NAND-based flash memory chips, however, any type of memory chips or combination of memory chips may also be utilized. In certain embodiments, the memory device 102 may be configured to store received data in volatile memory 110 (which may be any type of volatile memory) on a non-persistent basis. In certain embodiments, the volatile memory 110 may include componentry, such, as but not limited to, a physical memory array.

In certain embodiments the firmware 150 of the memory device 102 may be configured to control the operative functionality of the memory device 102. In certain embodiments, the firmware 150 may be configured to manage all operations conducted by the controller 106. In certain embodiments, the firmware 150 may be configured to activate a physical row in the memory banks 108, the memory banks 118, or a combination thereof, such as in response to receipt of an activate command by the host device 130. In certain embodiments, the firmware 150 may be configured to deactivate or close a physical row in the memory banks 108, the memory banks 118, or a combination thereof, such as if a precharge command is received from the host device 130, a precharge command is issued by the memory device 102 itself, or a combination thereof. In certain embodiments, the firmware 150 may be configured to initiate memory management operations, such as, but not limited to, a memory management read operation, a memory management write operation, other memory management functions or operations, any other functions and/or operations described herein, or a combination thereof.

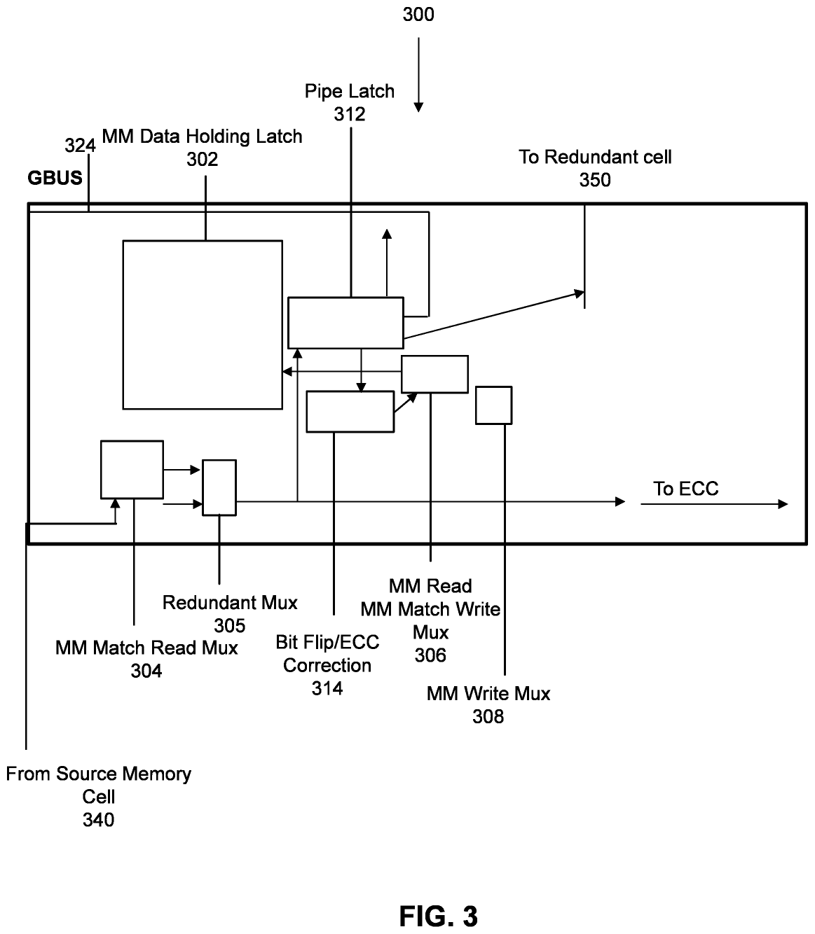

In certain embodiments, the memory device 102 may include a holding register 127. In certain embodiments, the holding register 127 may include any of the features and/or functionality of a memory register that may be utilized with a memory device, such as memory device 102. In certain embodiments, the holding register 127 may be utilized to store data and error correction parity bits associated with data, such as during the performance of memory management operations (e.g., part of a memory management function to balance the use of memory cells in the memory device 102). In certain embodiments, the holding register 127 may include any number of memory latches and may be configured to store any number of bits of data (e.g., user data and/or any other type of data), parity bits (e.g., error correction parity bits utilize to correct data), or a combination thereof. In certain embodiments, the holding register 127 may serve to temporarily hold data and parity bits between a memory management read operation and a memory management write operation of a memory management function. For example, for a memory management function to be performed on the memory device 102, the memory management read operation may be utilized to activate (e.g., by utilizing an activate command) and open a source memory cell (or row) of a memory bank 108 and then read the stored data from the activated source memory cell. In certain embodiments, the data read from the source memory cell may be provided to a circuit (e.g., circuits 300, 400 as illustrated in FIGS. 3-13) and the data may be stored in the holding register 127 of the circuit. When it comes time to execute the memory management write operation of the memory management function, the data stored in the holding register 127 may be transferred to the target memory cell (or row) for storage. Notably, the system 100 including the memory device 102 may be utilized to support any of the functionality provided by the present disclosure.

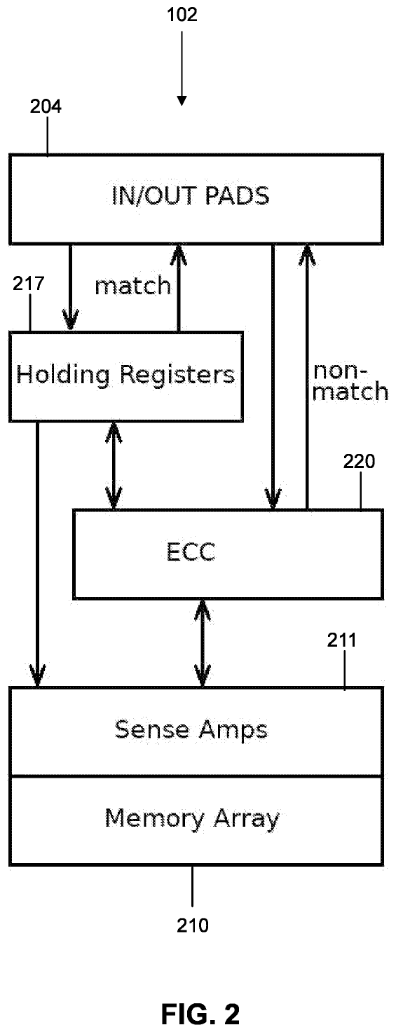

Referring now also to FIG. 2, a schematic diagram of a memory device 102 illustrating holding register 217 traffic flows in accordance with embodiments of the present disclosure is shown. In certain embodiments, the memory device 102 of FIG. 2 may be the same memory device 102 from FIG. 1, however, in certain embodiments, the memory device 102 from FIG. 2 may be different from the memory device 102 from FIG. 1. In certain embodiments, any of the components of memory device 102 from FIG. 2 may be incorporated into the memory device 102 of FIG. 1 and vice versa. In certain embodiments, the memory device 102 may include input/output pads 204 (or input-output pads), holding registers 217 (which may be the same as holding register 127), an ECC engine 220, sense amplifiers 211 (which may be the same as sense amplifiers 111), a memory array 210 including any number of memory cells containing memory rows and columns for storing data, any other components, or a combination thereof. In certain embodiments, the input/output pads 204 may be the component(s) by which the memory device 102 receives signals including data from a host device 130, transmits signals including data to a host device 130, communicates with other devices, or a combination thereof. In certain embodiments, commands for controlling the memory device 102 may be issued by the host device 130 to the memory device 102 via the input/output pads 204. In certain embodiments, the input/output pads 204 may include and/or be connected to a global data bus through which data and/or commands are communicated between the memory device 102, the host device 130, other devices, or a combination thereof. In certain embodiments, requests to read data, modify data, erase data, replace data, and/or otherwise interact with data may be received via the input/output pads 204, such as from a host device 130. In certain embodiments, responses to the requests that may include requested data may be transmitted to the host device 130 (or other requesting device) via the input/output pads 204.

In certain embodiments, the holding register 217 may be one or more holding registers 217, which may include any number of memory latches that may be configured to store data. In certain embodiments, the holding register 217 may include any number of addresses that may be utilized to identify locations in the holding registers 217 where data is stored. In certain embodiments, holding registers 217 may be added per memory page, memory bank, and/or bank group of a memory device 102. In certain embodiments, the holding register 217 may be configured to store data, parity bits for error correction, any other information, or a combination thereof. In certain embodiments, the holding register 217 may reside in a circuit 300, 400, a bit slice of the memory device 102, or a combination thereof. In certain embodiments, the circuit (e.g., circuit 300, 400) containing the holding register 217 may be configured to receive data from and/or provide data to the memory array 210 of the memory device 102, a host device 130, the ECC engine 220, the sense amplifiers 211, any other components of the system 100, or a combination thereof. In certain embodiments, the circuit containing the holding register 217 may be configured to be positioned into a datapath of the memory device between the sense amplifiers 211 and the input/output pads 204. In certain embodiments, the circuit containing the holding register 217 may be positioned into a datapath of the memory device between the input/output pads 204 and the ECC engine 220. In certain embodiments, the circuit containing the holding register 217 may be positioned in a datapath of the memory device 102 such that the circuit is positioned to have direct access to the ECC engine 220, the input/output pads 204, and the sense amplifiers 211. In certain embodiments, the holding register 217 may serve as the location that data is sent from a memory cell that is undergoing a memory management-related operation. For example, if a source memory cell (e.g., source memory cell 340) of the memory array 210 is the target of a memory management read operation of the memory management function, the source memory cell may be activated and the data may be provided from the source memory cell to the sense amplifiers 211.

In certain embodiments, the data from the sense amplifiers 211 may be provided to the ECC engine 220 to calculate parity bits (i.e., error correction parity bits) that may be utilized to correct and reconstruct the associated data in the event that the data gets corrupted or contains errors. In certain embodiments, the ECC engine 220 may be controlled by the controller 106 and may include and/or utilize the encoder 160 for generating ECC data (e.g., such as when writing data to the memory device 102), and a decoder 162 for decoding ECC data (e.g., when reading data from the memory device 102). In certain embodiments, the ECC engine 220 may also correct the data if there are errors contained in the data. In certain embodiments, functionality and features provided by the ECC engine 220 may be integrated into the bit flip/error correction component 314. In certain embodiments, once the parity bits for the data are calculated and the data and/or parity bits are corrected (if errors in either or both are detected), the data and the associated parity bits may be stored in the holding register 217.

While the data and associated parity bit(s) are stored in the holding register 217 and before the execution of the memory management write operation of the memory management function that transfers the data and/or parity bits from the holding register 217 to a target memory cells of the memory array 210, a host device 130 may transmit requests to access and/or modify the data stored in the holding register 217. For example, the host device 130 may issue a read request that may be received via the input/output pads 204 of the circuit 300, 400 and if the address of the data to read in the read request matches a holding register address for the holding register 217, the data and/or parity bits may be provided to the host device 130 via the input/output pads 204. If, however, the address specified in the request does not match an address of the holding register 217, the address may match an address for a row in the memory array 210 or there may be an error associated with the address specified. In certain embodiments, the ECC engine 220 may error correct data and/or parity bits and/or calculate the parity bits and provide the foregoing to the host device 130 via the input/output pads 204.

Referring now also to FIGS. 3-13, exemplary datapath flows between components of circuits 300, 400 of a memory device 102 are shown for various types of operations that may be executed or performed with respect to the memory device 102. In certain embodiments, the circuits 300, 400 may be bit slices and may include a plurality of components to support the functionality of the present disclosure. For example, in certain embodiments, the circuits 300, 400 may include an memory input/output 301, a memory management data holding latch 302 (or holding register), match read multiplexer 304, redundant multiplexer 305, match write multiplexer 306, write multiplexer 308, pipe latch 312, bit flip/error correction component 314, control multiplexer 316, a global data bus 324, any other components, or a combination thereof. FIG. 3 illustrates an exemplary memory management holding latch circuit implementation that includes a memory management match read multiplexer 304, a memory management data holding latch 302, a memory management read/match write multiplexer 306, and a memory management write multiplexer 308. The implementation shown in FIG. 3 provides a possible arrangement of the components and other arrangements of the components and the use of additional or fewer components may be utilized depending on the functionality needs or specification required.

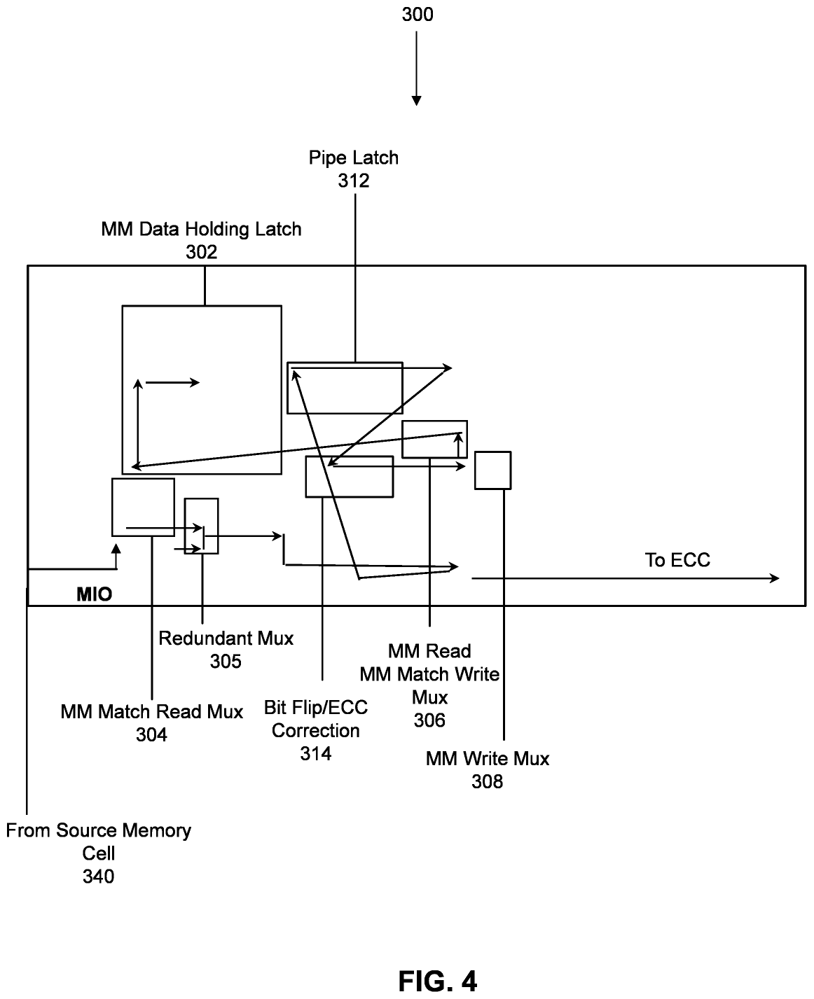

Referring now also to FIG. 4, an exemplary datapath flow for a memory management read operation (e.g., for a memory management function) for standard or normal data (e.g., user data or other data) is shown for a circuit 300, which may be communicatively linked to a host device 130 and to other memory components of the memory device 102. In certain embodiments, the circuit 300 may communicate with the host device 130 via the global data bus 324, and the circuit 300 may communicate with other memory components (e.g., memory cells of memory arrays, sense amplifiers, memory controller, etc.) via the memory input/output 301. For the memory management read operation, such as for memory management, a source memory cell 340 may be targeted for memory management. In certain embodiments, the source memory cell 340 may be activated via an activate command and the data and/or parity bits for reconstructing (and/or correcting) the data may be provided to the sense amplifiers of the memory device 102. The sense amplifiers may provide the data and/or parity bits to the memory input/output 301, which may provide the data to the memory management match read multiplexer 304. The data may be selected and provided as input to a redundant multiplexer 305. Another input, which may come from a redundant memory cell may also serve as an input to the redundant multiplexer 305. An input may be selected, and the data may be queued as an input to the pipe latch 312. The data may be outputted via the pipe latch 312 and provided to the bit flip/error correction component 314 to perform error correction on the data if one or more errors are detected in the data. The error corrected data may be provided to the memory management read/match write multiplexer 306, which may output the data to the memory management data holding latch 302 (i.e., holding register) for storage. In certain embodiments, the data may also be provided to an ECC engine to calculate parity bits for the data and/or to perform further error correction on the data.

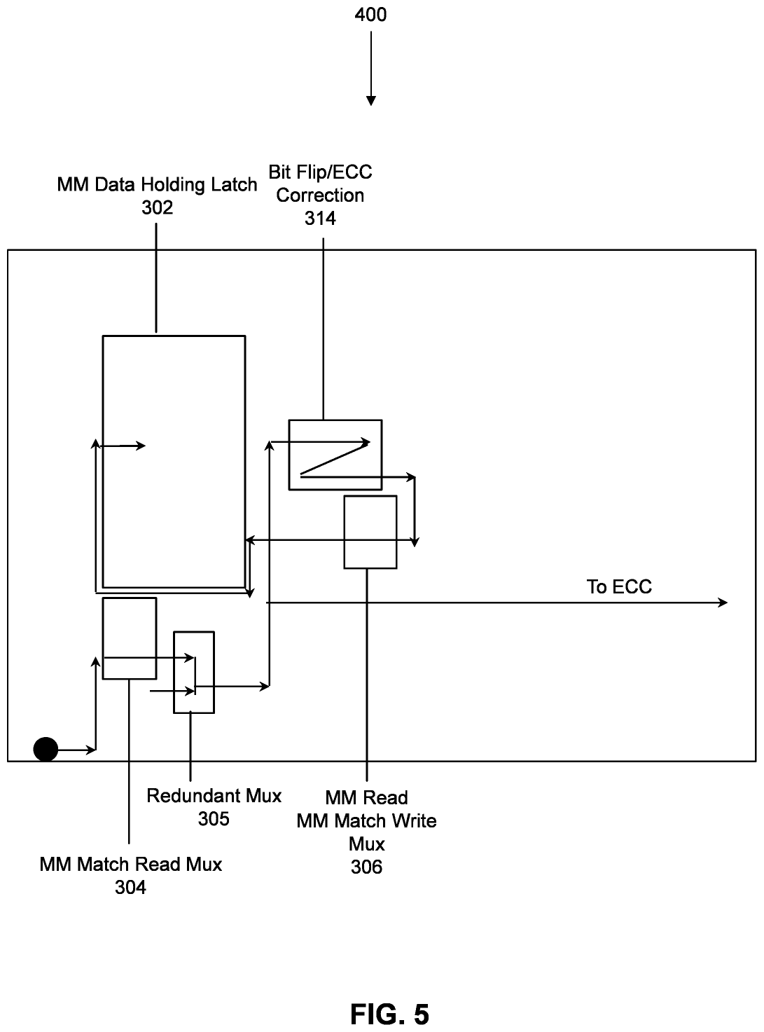

Referring now also to FIG. 5, an exemplary datapath flow for a parity bit(s) (e.g., error correction parity bit to correct data) is shown, such as for a circuit 400, which may be a bit slice block of an integrated circuit of the memory device 102. For example, for a memory management read operation for a memory management function to be performed for a source memory cell 340, the parity bit(s) for the data may be provided to sense amplifiers from the source memory cell 340 and then provided to the circuit 300 via the memory input/output 301. In certain embodiments, the parity bit(s) may be provided to the memory management read multiplexer 304 and then to the redundant multiplexer 305, which may also receive as a separate input, information from a redundant memory cell. The parity bit(s) selected by the redundant multiplexer 305 (e.g., P out) may be provided to the ECC engine 220 and/or bit flip/error correction component 314 for correction (if errors are detected), which may then provide the parity bit(s) to the match write multiplexer 306, which may provide the parity bit(s) to the memory management holding latch 302 for storage. A holding register address may be mapped or assigned to the data and/or the parity bit(s) associated with the data.

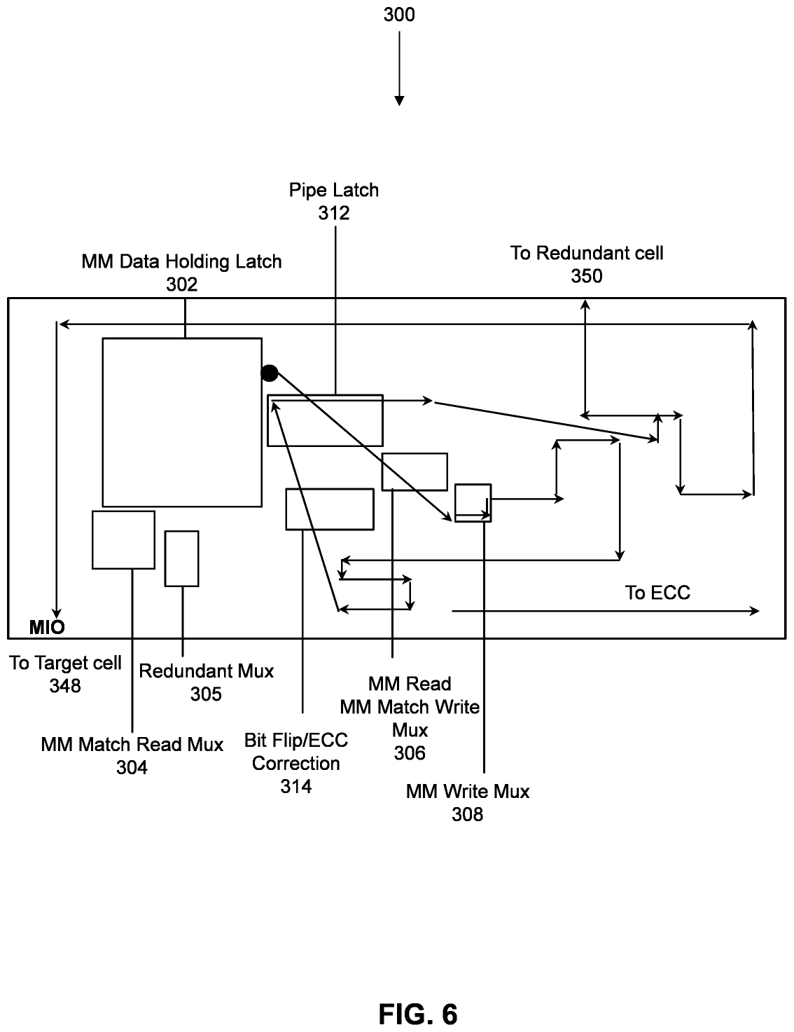

Referring now also to FIG. 6, an exemplary datapath flow for a memory management write operation (e.g., to complete the memory management function) for standard or normal data is shown for circuit 300. In certain embodiments, the memory management write operation may be conducted after the memory management read operation. In certain embodiments, the memory management write operation may be conducted within a predetermined time period or random time period after the read operation is completed. In certain embodiments, the memory management write operation may be utilized to transfer the data stored in the memory management holding latch 302 to the target memory cell of the memory array to complete the transfer from the source memory cell 340 to the target memory cell 348. In certain embodiments, the data stored in the memory management holding latch 302 may be transferred to memory management write multiplexer 308, which may select the data and provide the data to the pipe latch 312. The data may then be provided as an output from the pipe latch 312 and outputted via the memory input/output 301 to the sense amplifiers 211 and then ultimately from the sense amplifiers 211 to the target memory cell 348. Additionally, in certain embodiments, the data may also be provided as an output from the pipe latch 312 and outputted to a redundant memory cell 350.

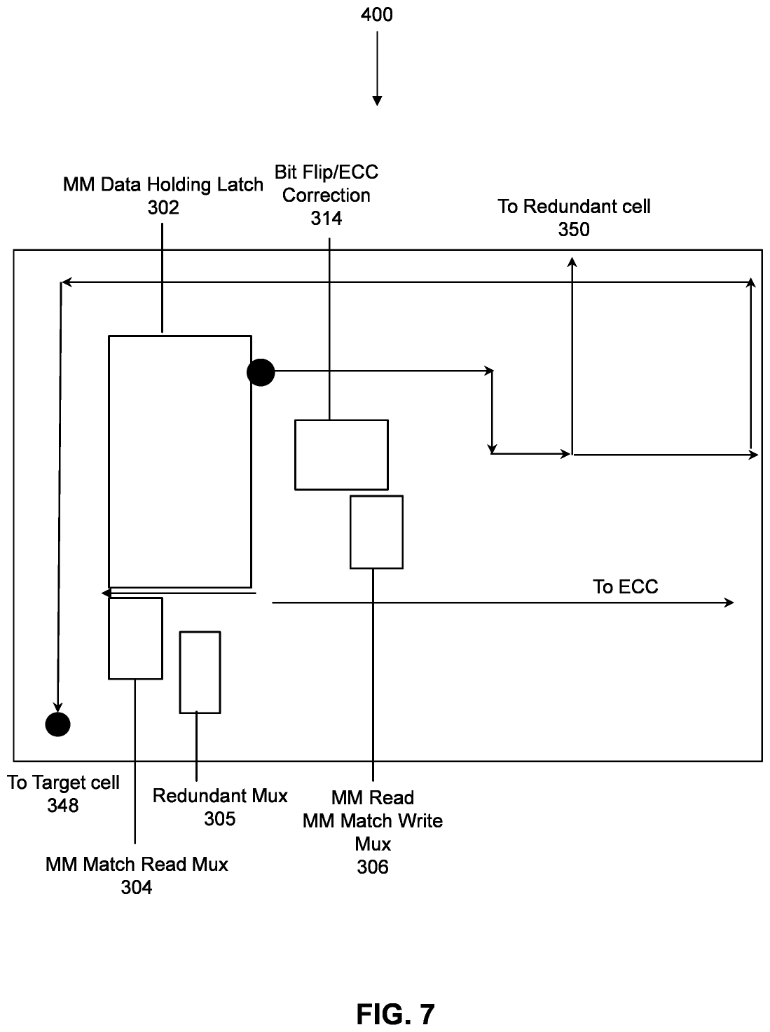

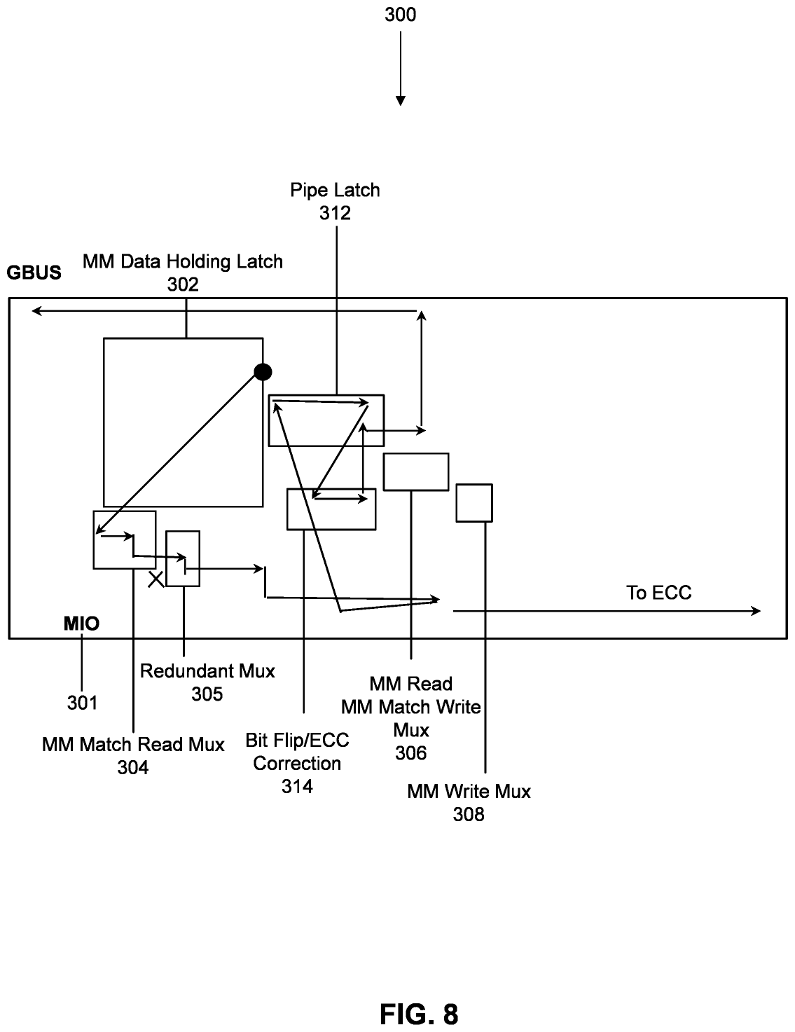

Referring now also to FIG. 7, an exemplary datapath flow for a memory management write operation (e.g. to complete the memory management function) for parity bits is shown for circuit 400. In certain embodiments, the parity bit(s) associated with the data may be retrieved from the memory management holding latch 302 and may be transferred to a redundant memory cell 350, to the target memory cell 348 via sense amplifiers 211, or a combination thereof. For example, the parity bit(s) may be transmitted to the memory input/output 301 to be provided to the target memory cell for storage. Referring now also to FIG. 8, an exemplary datapath flow for a memory management match read operation for standard or normal data is shown for circuit 300. In certain embodiments, the memory management match read operation may be conducted while the data and/or parity bits from the source memory cell 340 have been transferred to the memory management holding latch 302 for storage, but prior to the data and/or parity bits being transferred to the target memory cell. In certain embodiments, the memory manage read operation may be initiated via a request made by a host device 130 or other device or component. If the address specified in the request matches a holding latch (register) address for the holding latch 302, the data may be retrieved from the holding latch 302, provided to the memory management read multiplexer 304, the redundant multiplexer 305 (this time there is no need for an input from a redundant cell to the redundant multiplexer since the holding latch 302 data is stored after conducting redundant multiplexing previously). The data may then be provided to the ECC engine 220 and to the pipe latch 312. The data may then be provided to the bit flip/error correction component 314, and, if there are errors, the errors may be corrected and provided to the pipe latch 312 and then to the global data bus 324, which may be utilized to provide the data to the host device 130.

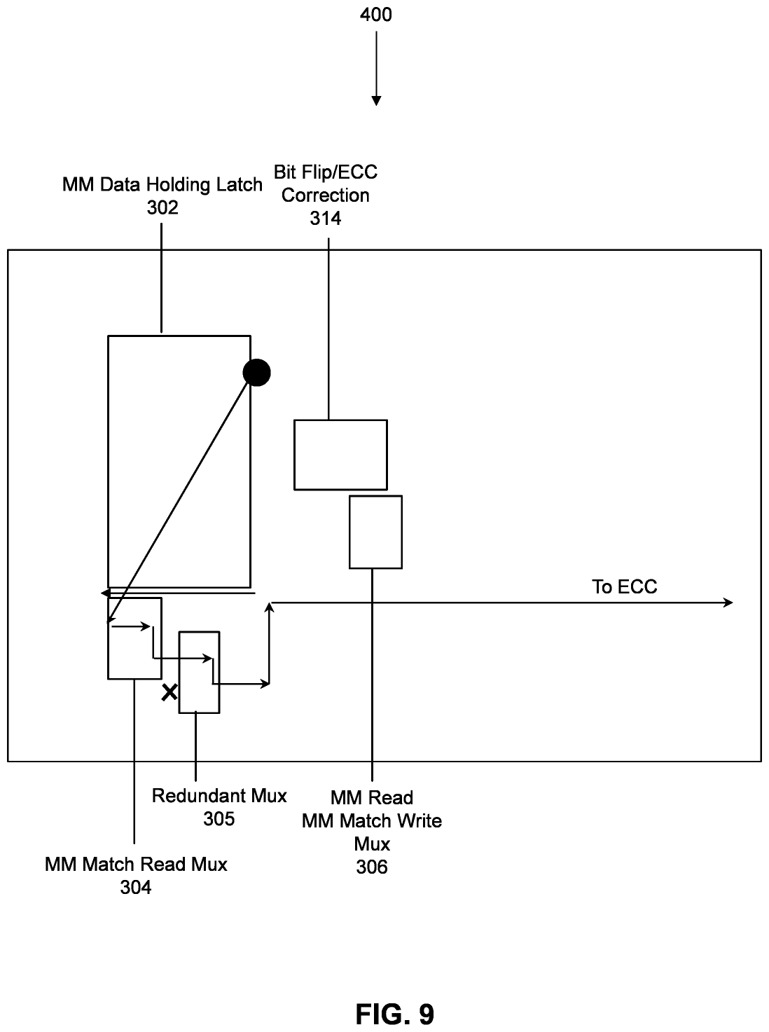

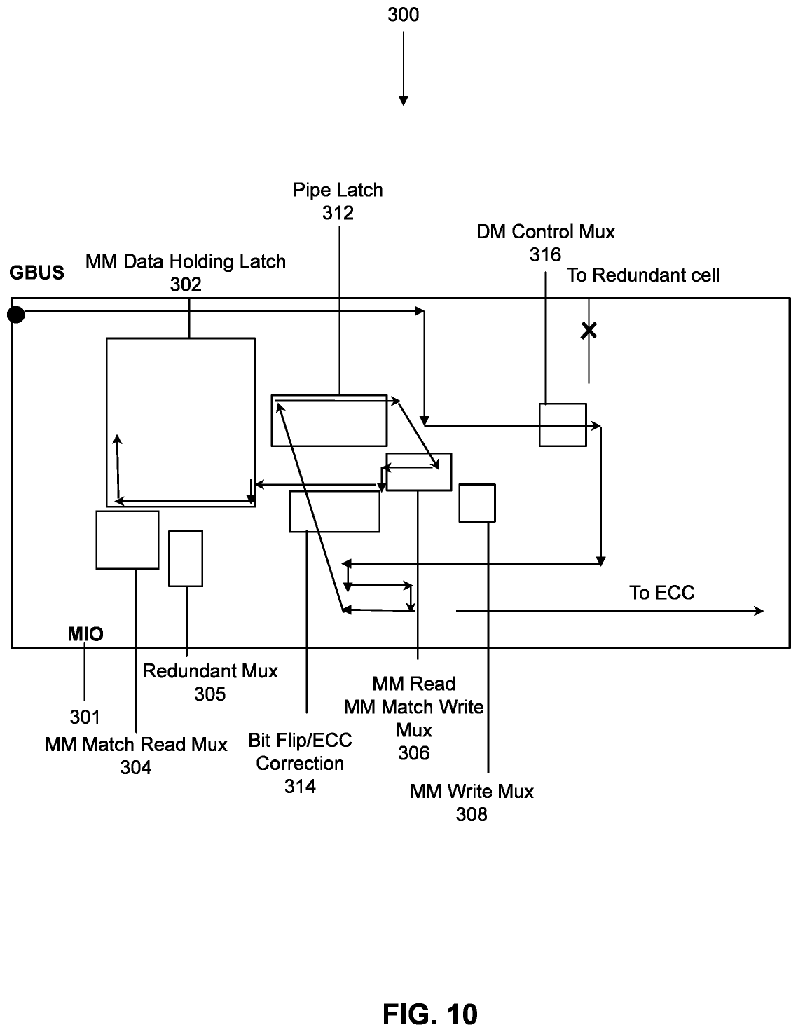

Referring now also to FIG. 9, an exemplary datapath for a memory management match read operation for parity bits is shown for circuit 400. In certain embodiments, parity bits associated with data stored in a holding latch address (i.e., holding register address) matching the address in the request for the data, may be retrieved from the memory management holding latch 302 and provided to the memory management read multiplexer 304 and then to the redundant multiplexer 305 (as with the normal data there is no need for an input from a redundant cell to the redundant multiplexer since the holding latch 302 parity bits are stored after conducting redundant multiplexing previously. In certain embodiments, the retrieved parity bit(s) may be provided to the ECC engine 220 to read the parity bit(s) and to perform any necessary calculations and/or error correction. Referring now also to FIG. 10, an exemplary datapath for a memory management match write operation for standard or normal data is shown for circuit 300. In certain embodiments, the request to write new data may be sent by a host device 130 and, if the address in the request matches the host latch address for the memory management latch 302, the new data may be written to the memory management holding latch 302. Specifically, the new data associated with the request may be received from the host device 130 via the global data bus 324 and sent to the control multiplexer 316, the pipe latch 312, the memory management write multiplexer 306, and then to be written at the matching holding latch address of the memory management holding latch 302 to overwrite the previously stored data in the holding latch 302 that was obtained from the source memory cell 340. In certain embodiments, the new data may also be provided to the ECC engine 220 to calculate new parity bits for the new data.

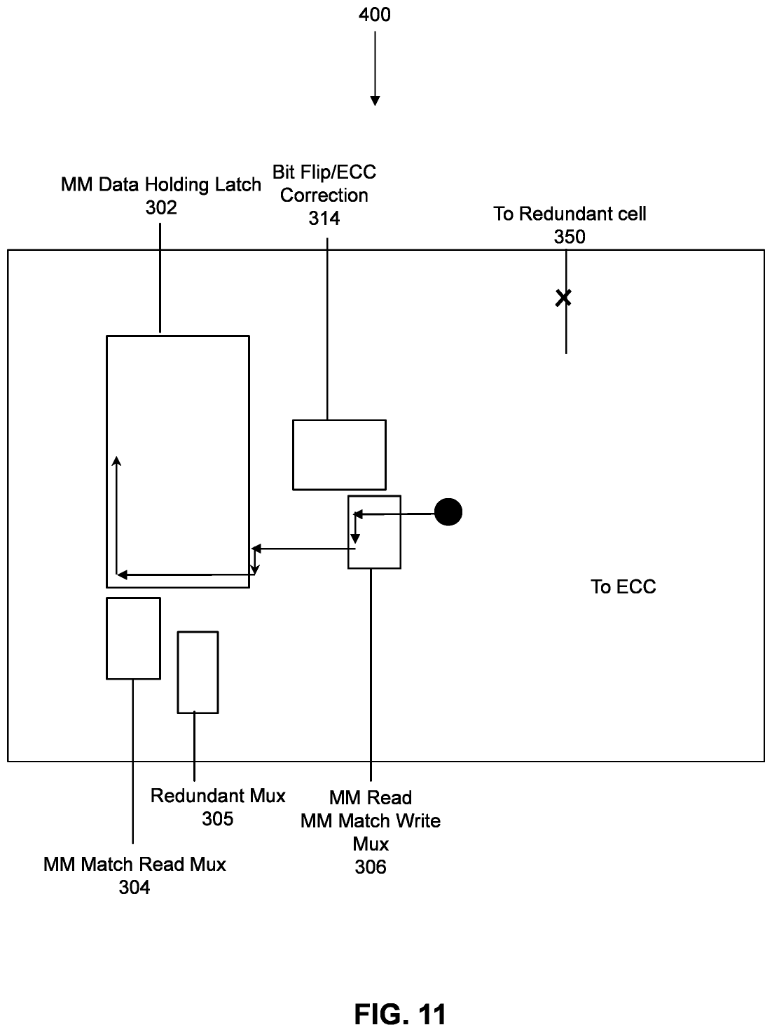

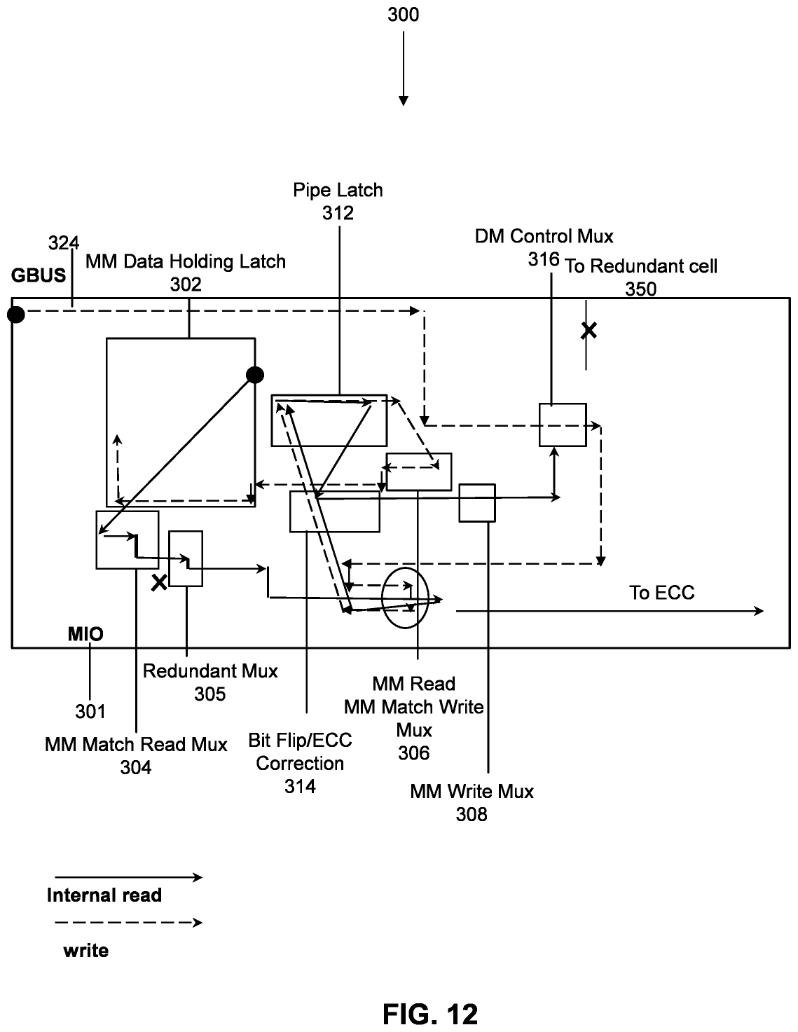

Referring now also to FIG. 11, an exemplary datapath for parity bits for a memory management match write operation is shown for circuit 400. In certain embodiments, the new parity bits calculated for the new data may be provided to the memory management match write multiplexer 306 and then to the memory management holding latch 302 for storage at a holding latch address of the memory management holding latch 302. Referring now also to FIG. 12, an exemplary datapath for a memory management match mask write operation for standard or normal data for circuit 300 is shown. For a memory management match mask write operation, the host device 130, for example, may transmit a request to overwrite only a portion of the data at an address and leave the remaining portion of the data at the address unchanged. In such a scenario, the new data may be specified in the request and a mask may be utilized for the portion of the data at the address that is not to be overwritten and is to remain unchanged. In certain embodiments, the new data associated with the request may come into the circuit 300 via the global data bus 324 and input/output pads 204 from the host device 130. In certain embodiments, the new data may be provided to the control multiplexer 316. Concurrently, data stored in the holding latch 302 (assuming the address in the request matches the holding latch address) may be outputted to the memory management match read multiplexer 304, to the redundant multiplexer 305, and then mixed or otherwise combined with the new data received from the control multiplexer 316. In certain embodiments, the mixed or combined data including the new data and the remaining unchanged data may be provided to the pipe latch 312, which may provide the mixed or combined data to the bit flip/error correction component 314 to perform error corrections and then to the control multiplexer 316. Additionally, the combined or mixed data may be provided to the holding latch 302 for storage at the holding register address matching the address from the request made by the host device 130.

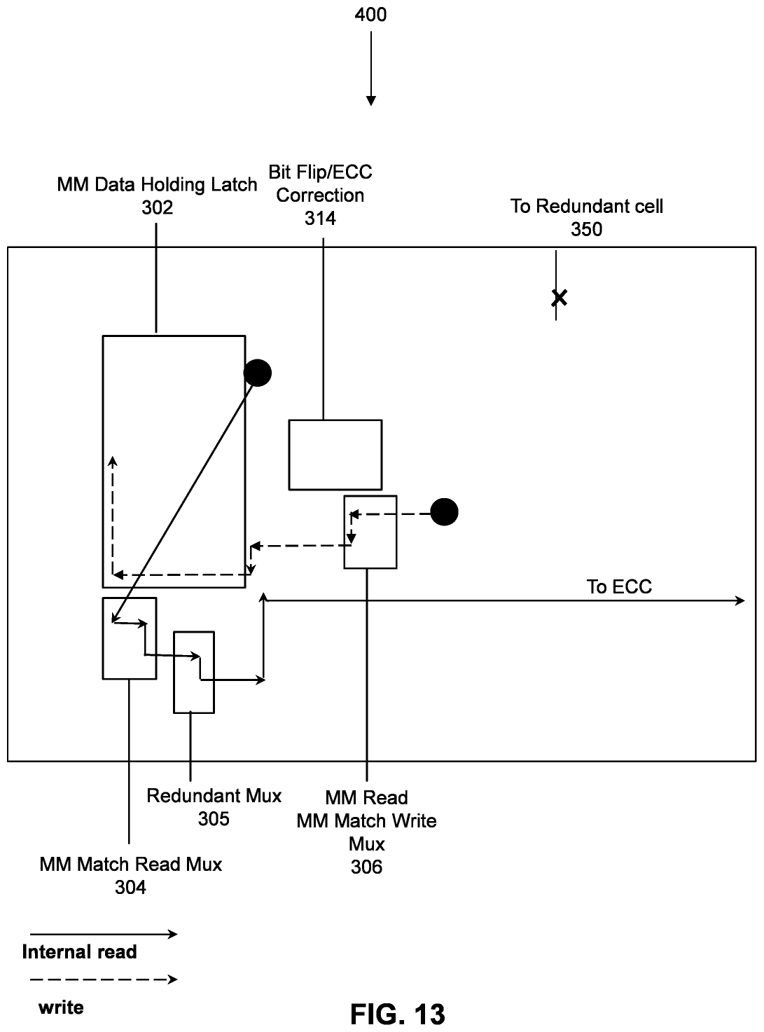

Referring now also to FIG. 13, an exemplary data path for parity bits for a memory management mask write operation is shown for circuit 400. For the memory management mask write operation, the parity bits stored in the holding latch 302 may be outputted to the memory management match read multiplexer 304, provided to the redundant multiplexer 305 and then to the ECC engine to calculate the new parity for the mixed (or combined) data the contains the new data and the unchanged data. In certain embodiments, the new parity bits may be provided to the memory match write multiplexer 306 and then to the memory management holding latch 302 for storage. In certain embodiments, control signaling for the holding register (i.e. latch (es)) may be generated in the memory device 102. In certain embodiments, when generating input/output control signals of the holding register during a memory management read operation and memory management write operation, the control signals may be shared with the control signal for the pipe latch 312 to minimize the number of sockets utilized. In certain embodiments, for the control signal of the pipe latch 312, the PIN<0> and POUT<0> signals may be enabled and the remaining signals may be turned off. In certain embodiments, the column address of a memory management match and/or write operation may utilize a column address signal for a redundant column of the memory device 102.

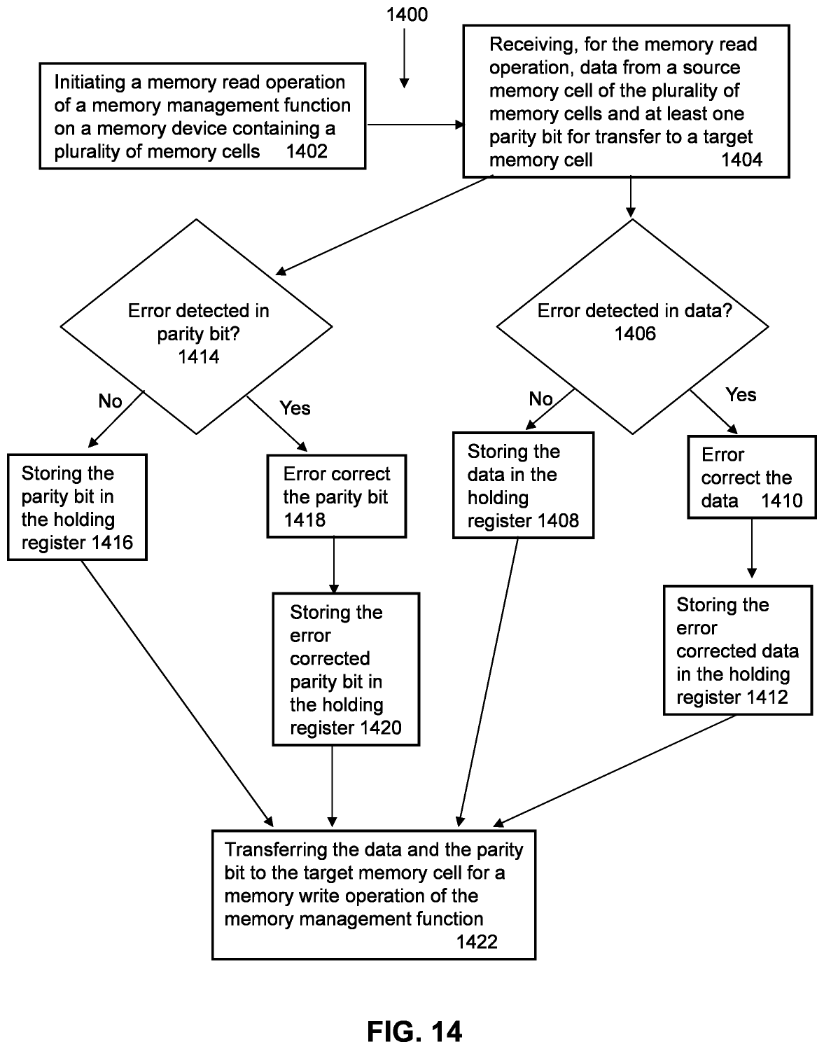

Referring now also to FIG. 14, FIG. 14 illustrates an exemplary method 1400 for providing memory management holding latch placement and control signal generation according to embodiments of the present disclosure. For example, the method of FIG. 14 can be implemented in the system 100 of FIG. 1 and any of the other systems or devices illustrated in the Figures or otherwise. In certain embodiments, the method of FIG. 14 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 14 may be performed at least in part by utilizing one or more processing devices (e.g., controller 106 of FIG. 1), the memory banks 108, 118, the holding register 127, the memory interface 101, the host device 130, or a combination thereof. Although shown in a particular sequence or order, unless otherwise specified, the order of the processes may be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 1400 may include steps for providing memory management holding latch placement and control signal generation according to various embodiments of the present disclosure. In certain embodiments, the method 1400 may be performed by utilizing the system 100, by utilizing any combination of the componentry contained therein, any of the components, systems, and/or programs described herein and/or in the Figures, or a combination thereof. In certain embodiments, the method 1400 may include performing steps to execute a memory management function on a memory device. In certain embodiments, the memory management function may include executing a memory management read operation that involves activating a source memory cell of a memory array that is the target of the memory management function and receiving the data from the source memory cell into a circuit containing a holding register of the memory device. In certain embodiments, before the data from the source memory cell is stored into the holding register, the method 1400 may include error correcting the data, error correcting parity bits utilized for correcting the data, or a combination thereof. The method 1400 may then store the data bits for the data, along with error correction parity bits associated with the data into the holding register. In certain embodiments, while the data and parity bits are stored in the holding register, a host device may transmit a request for the data. If the address specified in the request matches the holding register address (i.e., the address of the source memory cell previously holding the data) and the requested data is stored in the holding register, the data and/or parity bits may be read, modified, partially modified, or a combination thereof, based on the request made by the host device. In certain embodiments, the method 1400 may include transferring the data and/or parity bits associated with the data to a target memory cell, such as during a memory management write operation of the memory management function. Once the data is transferred to the target memory cell, the address associated with that data (i.e., the address of the source memory cell previously holding the data) is assigned to the target memory cell and the host device may transmit requests for the data using the address of the target memory cell.

At step 1402, the method 1400 may include initiating memory management read operation for a memory device containing a plurality of memory cells including one or more memory arrays. In certain embodiments, for example, the memory management read operation may be part of a memory management process to be executed on the memory device to prevent overuse of certain memory cells in the memory arrays over other memory cells in the memory arrays. In certain embodiments, the initiating of the memory management read operation may include transmitting an activate command to the memory device that specifies an address of a source memory cell of a memory array of the memory device that is the focus of the memory management operation. In certain embodiments, the activate command may activate the source memory cell that is the target of the memory management operation. Once the source memory cell is activated, the data may be transferred to sense amplifiers of the memory device so that the data may be sensed. In certain embodiments, the memory management read operation may be performed and/or facilitated by utilizing the memory device 102, the memory banks 108, 118, the memory interface 101, the controller 106, the holding register 127, any combination thereof, or by utilizing any other appropriate program, network, system, or device.

At step 1404, the method 1400 may include receiving, for the memory management read operation, the data from the source memory cell, one or more parity bits that may be utilized for error correcting the data, or a combination thereof. In certain embodiments, at step 1404, the data and/or one or more parity bits may be received from one or more sense amplifiers (e.g., sense amplifiers 111) of the memory device 102 that receive the data and parity bits from the source memory cell upon activation of the source memory cell. In certain embodiments, the data and/or one or more parity bits may be received by a circuit of the memory device 102 (e.g., circuit 300), which may include a match read multiplexer 304, a redundant multiplexer 305, a match write multiplexer 306, a write multiplexer 308, a pipe latch 312, a bit flip/error correction component 314, a control multiplexer 316, any other components, or a combination thereof. In certain embodiments, the parity bits may be utilized to facilitate error correction on the data that the parity bits are associated with. In certain embodiments, for example, the data and parity bits associated with the data may be passed to a match read multiplexer 304, which may provide the data and parity bits to the redundant multiplexer 305 that may select as an output either the output from the match read multiplexer 304 or data that may be received from a redundant memory cell that may also have the data and/or parity bits. In certain embodiments, the data bits may be passed to a pipe latch 312 that may be utilized to queue the data and speed up the processing of the data within the circuit. In certain embodiments, the data may then be passed from the pipe latch 312 to the bit flip/error correction component 314 of the circuit. In certain embodiments, the parity bit data may not need to be passed through a pipe latch 312 and may be passed to the bit flip/error correction component 314 from the redundant multiplexer 305. In certain embodiments, the data bits and the parity bit data may also be passed to an ECC engine 220 for error correction as well.

At step 1406, the method 1400 may include determining, such as by utilizing the bit flip/error correction component 314 whether there is an error in the data passed to the bit flip/error correction component 314. In certain embodiments, the determining of whether an error exists in the data may be performed and/or facilitated by utilizing the bit flip/error correction component 314, the memory device 102, the controller 106, the ECC engine 220, the circuit 300, the circuit 400, any combination thereof, or by utilizing any other appropriate program, network, system, or device. If there is determined to be no errors in the data at step 1406, the method 1400 may proceed to step 1408, which may include storing the data in step 1408, the method 1400 may include storing the data in the holding register 127 (or holding latch, which may include any number of latches). For example, in certain embodiments, the data may be passed from the bit flip/error correction component 314 to the match write multiplexer 306 and then to the holding register 127 for storage, such as in a latch of the holding register 127. In certain embodiments, the storing of the data in the holding register 127 may be performed and/or facilitated by utilizing the circuit 300, the memory device 102, the controller 106, any combination thereof, or by utilizing any other appropriate program, network, system, or device.

If, however, at step 1406, an error is detected in the data, the method 1400 may proceed to step 1410. At step 1410, the method 1400 may include error correcting the data to remove the errors detected in the data. In certain embodiments, the error correcting may be performed and/or facilitated by utilizing the bit flip/error correction component 314, the memory device 102, the controller 106, the ECC engine 220, the circuit 300, the circuit 400, any combination thereof, or by utilizing any other appropriate program, network, system, or device. Once the error(s) in the data are corrected, the method 1400 may proceed to step 1412. At step 1412, the method 1400 may include storing the error corrected data in the holding register 1412. In certain embodiments, the storing of the error corrected data in the holding register may be performed and/or facilitated by utilizing the circuit 300, the memory device 102, the controller 106, any combination thereof, or by utilizing any other appropriate program, network, system, or device.

In certain embodiments, the method 1400 may proceed to step 1414. In certain embodiments, step 1414 may occur during step 1406 or at any other desired time. At step 1414, the method may include determining whether there are any errors in the parity bit(s) associated with the data obtained from the source memory cell. In certain embodiments, the determining of may be performed and/or facilitated by utilizing the circuit 300 (e.g., bit flip/error correction component 314), the memory device 102, the controller 106, any combination thereof, or by utilizing any other appropriate program, network, system, or device. If, at step 1414, there is no error detected in the parity bit(s) associated with the data, the method 1400 may proceed to step 1416. At step 1416, the method 1400 may include storing the parity bit(s) associated with the data in the holding register 127 of the memory device 102. In certain embodiments, the storing of the parity bit(s) associated with the data in the holding register 127 may be performed and/or facilitated by utilizing the circuit 300, the memory device 102, the controller 106, any combination thereof, or by utilizing any other appropriate program, network, system, or device.

If, however, at step 1414, there are one or more errors detected in the parity bit(s) associated with the data, the method 1400 may proceed to step 1418. At step 1418, the method 1400 may include error correcting the parity bit(s) to remove and/or correct the errors detected in the parity bits(s). In certain embodiments, the error correcting of the parity bit(s) may be performed and/or facilitated by utilizing the bit flip/error correction component 314, the memory device 102, the controller 106, the ECC engine 220, the circuit 300, the circuit 400, any combination thereof, or by utilizing any other appropriate program, network, system, or device. Once the parity bit(s) are error corrected, the method 1400 may proceed to step 1420. At step 1420, the method 1400 may include storing the error corrected parity bit(s) in the holding register 127. In certain embodiments, the storing of the error corrected parity bit(s) may be performed and/or facilitated by utilizing the circuit 300, the memory device 102, the controller 106, any combination thereof, or by utilizing any other appropriate program, network, system, or device. In certain embodiments, depending on whether the method 1400 is at step 1416, 1420, 1408, and/or 1412, the method 1400 may then proceed to step 1422. At step 1422, the method 1400 may include transferring the data and the parity bit(s) to the target memory cell from the holding register 127, such as for a memory management write operation of the memory management function. In certain embodiments, the transferring of the data from the holding register 127 to the target memory cell (e.g., target memory cell 348) may be performed and/or facilitated by utilizing the circuit 300, the memory device 102, the controller 106, any combination thereof, or by utilizing any other appropriate program, network, system, or device.

Notably, the method 1400 may be repeated as desired and may incorporate any of the other functionality of the present disclosure and is not limited to the specific sequences of steps provide herein. In certain embodiments, for example, the method 1400 may incorporate steps for receiving and processing memory management match read operations, such as when a host device requests to read data having an address matching the holding register address storing the data and/or parity bit(s) associated with the data. In such a scenario, the host device may obtain the data from the holding register 127 before the data and/or parity bit(s) are transferred to a target memory cell, such as for a memory management write operation of a memory management function. In certain embodiments, the method 1400 may incorporate steps for receiving and processing memory management match write operations, such as when a host device requests to write (or otherwise modify) data having an address matching the holding register address storing the data and/or parity bit(s) associated with the data. In such a scenario, the host device may write new data to the holding register 127 to replace the existing data associated with the address and the new data, once written to the holding register 127, may be transferred to the target memory cell. In certain embodiments, for example, the method 1400 may further incorporate steps for receiving and processing memory management match mask write operations, such as when a host device requests to write new data to replace only a portion of the data stored in the holding register 127 and a remaining portion of the data is to remain the same (e.g., the mask portion of the request). In such a scenario, the method 1400 may replace the portion of the data in the holding register with the new data, but maintain the remaining portion of the data. The mixed previously stored data and the new data may then be transferred to a target memory cell. Notably, the method 1400 may incorporate any of the functionality described in the present disclosure as well.

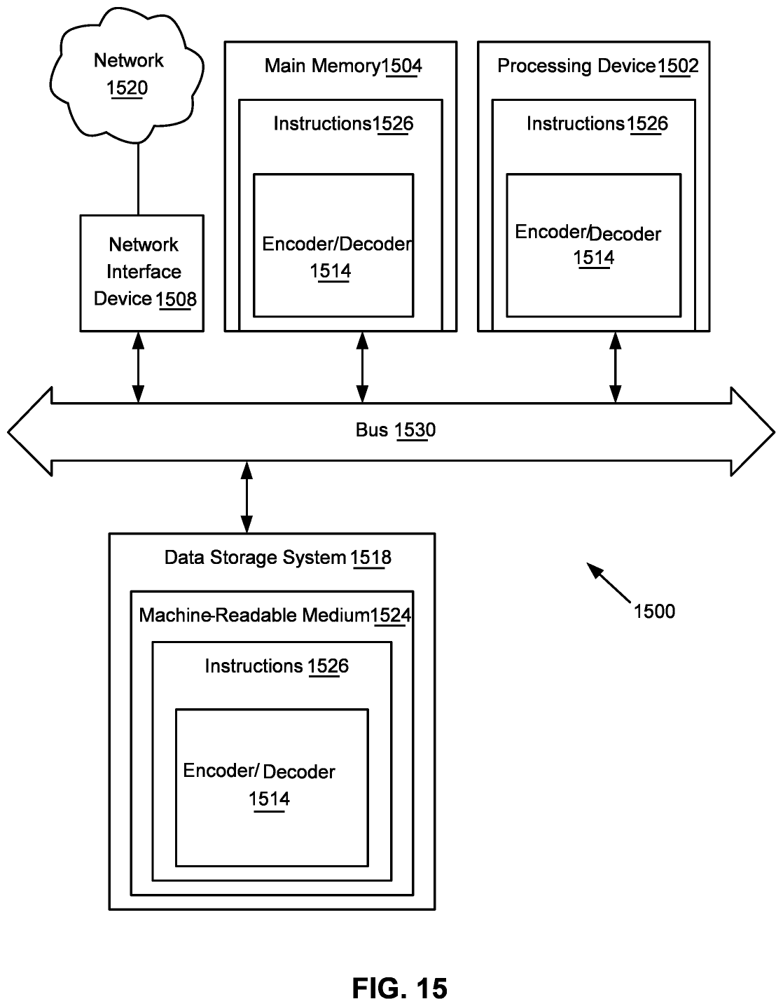

FIG. 15 illustrates an exemplary machine of a computer system 1500 within which a set of instructions, for causing the machine to perform any one or more of the methodologies discussed herein, can be executed. In certain embodiments, the computer system 1500 can correspond to a host system or device (e.g., the host device 130 of FIG. 1) that includes, is coupled to, or utilizes a memory system (e.g., the memory device 102 of FIG. 1). In certain embodiments, computer system 1500 corresponds to memory device 102, host device 130, or a combination thereof. In certain embodiments, the machine may be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment. In certain embodiments, the machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

In certain embodiments, the exemplary computer system 1500 may include a processing device 1502, a main memory 1504 (e.g., read-only memory (ROM), flash memory, dynamic random-access memory (DRAM) such as synchronous DRAM (SDRAM) or Rambus DRAM (RDRAM), static random-access memory (SRAM), etc.), and/or a data storage system 1518, which are configured to communicate with each other via a bus 1530 (which can include multiple buses). In certain embodiments, processing device 1502 may represent one or more general-purpose processing devices such as a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In certain embodiments, the processing device 1502 may also be one or more special-purpose processing devices such as an application specific integrated circuit (ASIC), a field programmable gate array (FPGA), a digital signal processor (DSP), network processor, or the like.

The processing device 1502 is configured to execute instructions 1526 for performing the operations and steps discussed herein. For example, the processing device 1502 may be configured to perform steps of the method 1400 and support functionality provided by the system 100. For example, in certain embodiments, the computer system 1500 may be configured to assist in initiating a memory management operation (e.g., of a memory management function), receiving data and error correction parity bits from a source memory cell of a memory device (e.g., memory device 102), determining whether data from the source memory cell and/or the parity bits contain errors, performing error correction on the data and/or the parity bits, storing the data and/or parity bits in a holding register of a memory device, transferring the data and/or parity bits stored in the holding register to a target memory cell, modify the data and/or parity bits stored in the holding register (e.g., in response to a write request by a controller), performing any other operations as described herein, or a combination thereof. As another example, in certain embodiments, the computer system 1500 may assist with conducting the operative functionality of the controller 106, holding registers, 127, 217, the non-volatile memory 104, the volatile memory 110, the memory device 102, the host device 130, the input/output pads 204, the sense amplifiers 111, 211, the error correction engine 220, circuit 300, circuit 400, holding latch 302 (or register), match read multiplexer 304, redundant multiplexer 305, match write multiplexer 306, write multiplexer 308, pipe latch 312, bit flip/error correction component 314, control multiplexer 316, any other components, or a combination thereof. In certain embodiments, computer system 1500 may further include a network interface device 1508 to communicate over a network 1520.

The data storage system 1518 can include a machine-readable storage medium 1524 (also referred to as a computer-readable medium herein) on which is stored one or more sets of instructions 1526 or software embodying any one or more of the methodologies or functions described herein. The instructions 1526 can also reside, completely or at least partially, within the main memory 1504 and/or within the processing device 602 during execution thereof by the computer system 1500, the main memory 1504 and the processing device 1502 also constituting machine-readable storage media. The machine-readable storage medium 1524, data storage system 1518, and/or main memory 1504 can correspond to the memory device 102, or a combination thereof.

Reference in this specification to “one embodiment” “an embodiment” or “certain embodiments” may mean that a particular feature, structure, or characteristic described in connection with the embodiment is included in at least one embodiment of the disclosure. The appearances of the phrases “in one embodiment” and “in certain embodiments” in various places in the specification are not necessarily all referring to the same embodiment(s), nor are separate or alternative embodiments mutually exclusive of other embodiments. Moreover, various features are described which may be exhibited by some embodiments and not by others. Similarly, various requirements are described which may be requirements for some embodiments, but not other embodiments.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software, or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. A memory device, comprising:
at least one memory array comprising a plurality of memory cells configured to store data;
and
a circuit configured to:
receive, for a memory management read operation of a memory management function, data from a source memory cell of the plurality of memory cells and at least one error correction parity bit associated with the data for transfer to a target memory cell of the plurality of memory cells;
perform error correction on the data based on the data from the source memory cell having a data error;
perform error correction on the at least one error correction parity bit based on the at least one error correction parity bit having a parity bit error; and
store, in a holding register, the data and the at least one error correction parity bit until the data and the at least one error correction parity bit are transferred to the target memory cell.

2. The memory device of claim 1, wherein the circuit is further configured to transfer, for a memory management write operation of the memory management function, the data, the at least one error correction parity bit, or a combination thereof, from the holding register to the target memory cell.

3. The memory device of claim 1, wherein the circuit is further configured to transfer, for a memory management write operation and from the holding register, the data, the at least one error correction parity bit, or a combination thereof, to a redundant memory cell of the plurality of memory cells.

4. The memory device of claim 1, wherein the circuit is further configured to maintain a mapping of the data stored in the holding register to a source row address of the source memory cell while the data is stored in the holding register.

5. The memory device of claim 1, wherein the circuit is further configured to:
receive, from a controller, a request to read the data;
determine whether an address associated with the request to read the data matches with a source row address of the source memory cell mapped to the holding register storing the data; and
provide, if the address associated with the request matches with the source row address mapped to the holding register storing the data, the data from the holding register to the controller.

6. The memory device of claim 5, wherein the circuit is further configured to perform error correction on the data stored in the holding register prior to providing the data from the holding register to the controller in response to the request to read the data.

7. The memory device of claim 1, wherein the circuit is further configured to:
receive, from a controller, a request to write new data;
determine whether an address associated with the request to write the new data matches with a source row address of the source memory cell mapped to the holding register storing the data; and
write, if the address associated with the request matches with the source row address mapped to the holding register storing the data, the new data received from the controller to the holding register.

8. The memory device of claim 7, wherein the circuit is further configured to:
calculate at least one error correction parity bit for the new data; and
store the at least one error correction parity bit for the new data in the holding register.

9. The memory device of claim 1, wherein the circuit is further configured to:
receive, from a controller, a request to perform a mask write operation to overwrite a portion of the data with new data;
determine whether an address associated with the request to perform the mask write operation matches with a source row address of the source memory cell mapped to the holding register storing the data;
retrieve, if the address matches with the source row address mapped to the holding register storing the data, a remaining portion of the data from the holding register;
combine the new data with the remaining data to create combined data; and
store the combined data into the holding register.

10. The memory device of claim 9, wherein the circuit is further configured to:
calculate at least one error correction parity bit for the combined data; and
store the at least one error correction parity bit for the combined data in the holding register.

11. The memory device of claim 1, wherein the circuit is further configured to correct a soft error associated with the data on a subsequent request to read the data from the holding register.

12. A method comprising:
storing, in a holding register of a circuit of a memory device, data and at least one error correction parity bit associated with the data that is received from a source memory cell of the memory device, wherein the data is for a memory management read operation is associated with a memory management function associated with a command;
receiving, from a controller, a request to read the data;
determining whether an address associated with the request to read the data matches with a source row address of the source memory cell mapped to the holding register storing the data;
providing, if the address associated with the request matches with the source row address mapped to the holding register storing the data, the data from the holding register to the controller; and
transferring, from the holding register and for a memory management write operation associated with the memory management function, the data and the at least one error correction parity bit associated with the data to a target memory cell.

13. The method of claim 12, further comprising receiving the command to perform the memory management function on the memory device.

14. The method of claim 12, further comprising performing error correction on the data prior to storing the data in the holding register of the circuit of the memory device if the data is determined to have an error.

15. The method of claim 12, further comprising:
receiving, from the controller, a request to write new data;
determining whether an address associated with the request to write the new data matches with a source row address of the source memory cell mapped to the holding register storing the data;
writing, if the address associated with the request matches with the source row address mapped to the holding register storing the data, the new data received from the controller to the holding register;
calculating at least one error correction parity bit for the new data; and
storing the at least one error correction parity bit for the new data in the holding register.

16. The method of claim 12, further comprising:
receiving, from the controller, a request to perform a mask write operation to overwrite a portion of the data with new data;
retrieving, if an address associated with the request to perform the mask write operation matches with a source row address of the source memory cell mapped to the holding register, a remaining portion of the data from the holding register;
mixing the new data with the remaining data to create mixed data; and
storing the mixed data into the holding register.

17. A system comprising:
a host device comprising a controller; and
a memory device comprising:
at least one input-output pad;
a plurality of memory cells of at least one memory array;
at least one sense amplifier configured to sense stored data in the plurality of memory cells;
and
a circuit positioned into a datapath of the memory device and having access to the at least one sense amplifier and the at least one input-output pad via the datapath, wherein the circuit comprises a holding register and is configured to:
store, in a holding register of a circuit of a memory device, data and at least one error correction parity bit associated with the data that is received from a source memory cell of the plurality of memory cells, wherein the data is for a memory management read operation is associated with a memory management function associated with a command;
receive, from the controller, a request to write new data, wherein the request is received via the at least one input-output pad and the datapath;
determine whether an address associated with the request to write the new data matches with a source row address of the source memory cell mapped to the holding register storing the data;
write, if the address associated with the request matches with the source row address mapped to the holding register storing the data, the new data received from the controller to the holding register.

18. The system of claim 17, further comprising an error correction component positioned in the datapath of the memory device and having access to the circuit comprising the holding register via the datapath.

19. The system of claim 18, wherein the error correction component is positioned in the datapath such that the error correction component has access to the at least one sense amplifier.

20. The system of claim 17, further comprising an error correction component positioned in the datapath of the memory device and having access to the at least one input-output pad via the datapath.
